(19) United States
(12) Patent Application Publication
(10) Pub. No.: US 2026/0020365 A1
(43) Pub. Date: Jan. 15, 2026

(54) PHOTODIODE WITH DEEP TRENCH ISOLATION STRUCTURES AND INTERMEDIATE DOPED REGIONS

(71) Applicant: GlobalFoundries Singapore Pte. Ltd., Singapore (SG)

(72) Inventors: Ping ZHENG, Singapore (SG); Eng Huat Toh, Singapore (SG)

(21) Appl. No.: 18/770,537

(22) Filed: Jul. 11, 2024

(51) Int. Cl. H01L 27/146; H01L 31/0328; H01L 31/107

(52) U.S. Cl. CPC H10F 39/807; H10F 30/225; H10F 77/12

(57) ABSTRACT

A photodiode device includes a plurality of pixels, each of the pixels including a diode structure on a first side of a layer of semiconductor material and a lens on a second side of the layer of semiconductor material, a deep trench isolation (DTI) structure between adjacent pixels of the plurality of pixels, a first vertical conductive layer over a first side of the DTI structure, a second vertical conductive layer over a second side of the DTI structure, and a doped intermediate region between a contact at the first side of the layer of semiconductor material and a base of the DTI structure, and in direct contact with the contact and the first and second vertical conductive layers.

### BACKGROUND

Photodetectors are sensors that detect the presence of electromagnetic radiation. Semiconductor photodiodes are a category of photodetectors that use a P-N diode to convert incident photons into current. Photodiodes are used by many different technologies to sense one or more frequency of light, to determine the time at which transmitted light is reflected back to the photodiode, etc.

Avalanche photodiodes are a highly biased photodiodes in which photo-generated carriers are multiplied by avalanche breakdown in the device. Single photon avalanche diodes (SPADs) are avalanche photodiodes which are sensitive enough to detect the incidence of a single photon, and have lower noise and jitter than typical photodiodes. As technology progresses, there is an increasing demand for further miniaturization and improvements to photodiode technology.

### SUMMARY

Embodiments of the present disclosure are directed to a photodiode, a photodetector, and a method for forming a photodiode.

In an embodiment, a photodiode device includes a plurality of pixels, each of the pixels including a diode structure on a first side of a layer of semiconductor material and a lens on a second side of the layer of semiconductor material, a deep trench isolation (DTI) structure between adjacent pixels of the plurality of pixels, a first vertical conductive layer over a first side of the DTI structure, a second vertical conductive layer over a second side of the DTI structure, and a doped intermediate region between a contact at the first side of the layer of semiconductor material and a base of the DTI structure, and in direct contact with the contact and the first and second vertical conductive layers.

In an embodiment, a photodetector includes a photodiode device and a control circuit configured to control an operation of the photodiode device. The photodiode device includes a plurality of pixels, each of the pixels including a diode structure on a first side of a layer of semiconductor material and a lens on a second side of the layer of semiconductor material, a deep trench isolation (DTI) structure isolating adjacent pixels of the plurality of pixels from one another, a first vertical conductive layer over a first side of the DTI structure, a second vertical conductive layer over a second side of the DTI structure, and a doped intermediate region that extends between a contact at the first side of the layer of semiconductor material and a base of the DTI structure, and electrically couples the contact to the first and second vertical conductive layers.

In an embodiment, a method of forming a photodiode device includes forming diode structures on a first side of a layer of semiconductor material, forming a contact between two adjacent diode structures, forming a doped intermediate region over the contact, forming first and second vertical conductive layers electrically coupled to the doped intermediate region, forming a DTI structure between the first and second vertical conductive layers, and forming a lens on a second side of the semiconductor material. The first and second vertical conductive layers extend along sides of the DTI structure and the doped intermediate region electrically couples the contact to the first and second vertical conductive layers.

### BRIEF DESCRIPTION OF THE DRAWINGS

FIG. 1A illustrates a schematic diagram of a photodiode according to an embodiment.

FIG. 1B illustrates a simplified cross-sectional view of the photodiode of FIG. 1A according to an embodiment.

FIGS. 2A-2D illustrate simplified cross-sectional views of an embodiment of a process of forming the photodiode of FIG. 1B.

FIG. 3 illustrates a second embodiment of a photodiode.

FIG. 4 illustrates a photodetector according to an embodiment.

### DETAILED DESCRIPTION

A detailed description of embodiments is provided below along with accompanying figures. The scope of this disclosure encompasses numerous alternatives, modifications and equivalents. Although steps of various processes are presented in a particular order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

Although the terms “first” and/or “second” may be used herein to describe various elements, these elements should not be limited by these terms. These terms may be used merely to distinguish one element from another element. For instance, a first element discussed below could be termed a second element without departing from the teachings of the present disclosure. Similarly, the second element could also be termed the first element.

The drawings are not necessarily to scale and in some instances, proportions may have been exaggerated to clearly illustrate features of the embodiments. When a first element is referred to as being “on” a second element or “on” a substrate, it not only refers to a case where the first element is formed directly on the second element or the substrate but also a case where a third element exists between the first element and the second element or the substrate. An element “connected” or “coupled” to or with another element may be directly connected or coupled to or with the other element or, instead, one or more intervening elements may be present.

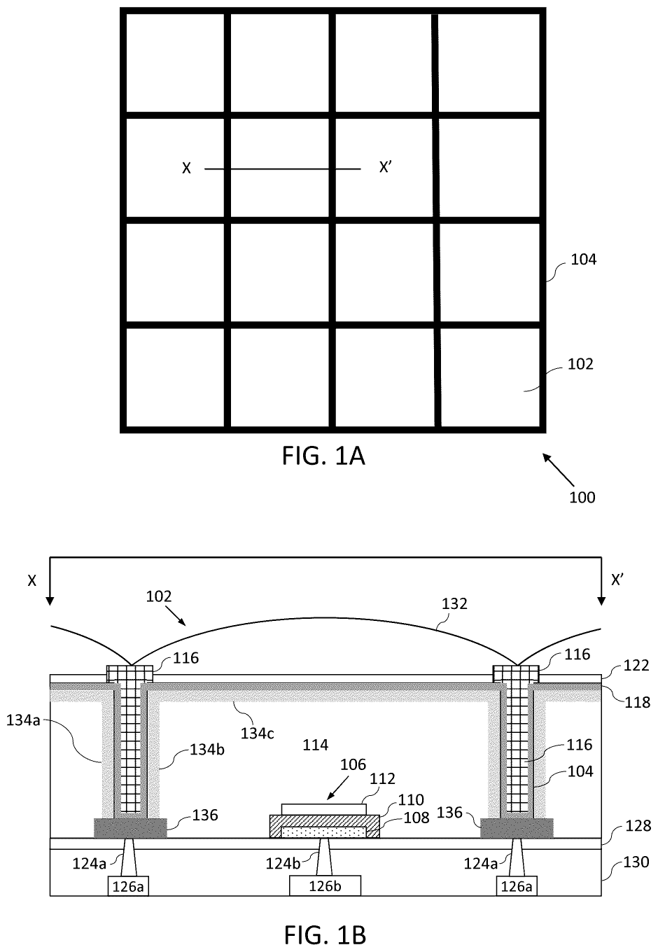

FIG. 1A illustrates a photodiode device 100 according to an embodiment of the present disclosure. The photodiode device 100 illustrated by FIGS. 1A and 1B is a backside illuminated (BSI) single photon avalanche diode (SPAD) photodiode device, but in other embodiments, the photodiode device can be an avalanche photodiode (APD) device, for example.

An APD is a type of photosensitive semiconductor device in which light is converted to electricity due to the photoelectric effect coupled with electric current multiplication as a result of avalanche breakdown. APDs differ from conventional photodiodes in that incoming photons internally trigger a charge avalanche. APDs can measure low levels of light and are widely used in long-distance optical communications and optical distance measurement where high sensitivity is needed.

SPADs are a type of APD that is sensitive enough to detect the incidence of a single photon. SPADs trigger an avalanche phenomenon with respect to the incidence of a single photon by applying a bias voltage higher than the breakdown voltage, and output a corresponding voltage pulse. The diode of an SPAD may employ a wide band-gap semiconductor material such as SiC, GaN, GaAs, AlN, AlAs, BN, GaP, AlP, ZnTe, MnTe, MgTe, ZnS, MgS, HgS, PbI2, TlPbI3, TlBr, TlBrI, or InAlP. In other embodiments, the SPAD may employ narrow band gap materials such as Ge, InGaAs, etc. Many materials including silicon, germanium and other III-V elements may be used to fabricate SPADs.

Returning to FIG. 1A, the photodiode device 100 has a plurality of pixels 102 that are separated by deep trench isolation (DTI) structures 104. The DTI structures 104 isolate the pixels 102 to prevent crosstalk between adjacent pixels. The photodiode device 100 may have any number of pixels 102 that define the resolution of the photodiode device 100. For example, when the photodiode device 100 is used in an image sensor, the device may have millions of pixels on a single chip, while a photodiode device 100 for a light detection and ranging (LiDAR) device may have only a few hundred or a few thousand pixels.

FIG. 1B illustrates an embodiment of a cross-section X-X′ of a pixel 102 of the photodiode device 100 illustrated in FIG. 1A. Each pixel 102 in the device includes a diode structure 106 on a first side of the substrate. The diode structures 106 include a first highly doped region 108 that may be doped with a first type of dopants, e.g. N dopants, a first well 110 that is doped with the first type of dopants and adjacent to the first doped region 108, and a second doped well 112 adjacent to the first doped well 110 and doped with a second type of dopants, e.g., P dopants. In another embodiment, the diode 106 has a first doped region 108 and a second doped well 112, and does not include the first well 110.

The diode structure 106 is disposed in a semiconductor material 114 that may be doped with the second type of dopants. When the first type of dopants are N dopants, the second type of dopants are P dopants. In such an embodiment, doped region 108 may be an N+ doped region, first doped well 110 may be an N well, second doped well 112 may be a P well.

The semiconductor material 114 may be an intrinsic material without any doping, or a lightly doped material. The semiconductor material may be an epitaxial silicon material or another semiconductor material such as germanium. Accordingly, the doped region 108, first doped well 110 and second doped well 112 may be doped silicon or doped germanium structures. The diode structure 106 may be formed of the same semiconductor material as semiconductor material 114 or a different semiconductor material as discussed above.

The diode structure 106 is surrounded by DTI structures 104. The DTI structures 104 include a conductive material 116 in a center portion of the structures, and the sidewalls and base of the trenches are lined with an insulating liner layer 118. The conductive material 116 may be a metal material such as tungsten, aluminum or copper, or a highly doped semiconductor material. The insulating liner layer 118 may be an oxide material such as silicon oxide or aluminum oxide.

An anti-reflective coating (ARC) layer 122 is disposed over the insulating liner layer 118 on a second side of the substrate which is a light-facing side of the device, and a micro-lens 132 is disposed over the anti-reflective coating layer 122. The anti-reflective coating layer 122 may be an oxide material such as titanium oxide, or a similar material as known in the art. A passivation layer (not shown), e.g. an aluminum oxide layer, may be present on the anti-reflective coating layer 122. The micro-lens 132 may focus photons toward the diode structure 106, and may be formed of a polymer or fused silica material.

A lateral conductive layer 134c is located under the insulating liner layer 118. The lateral conductive layer 134c may be a portion of a continuous conductive layer 134 that includes vertical conductive layers 134a and 134b which are disposed over and cover sides of the DTI structures 104. Accordingly, the lateral conductive layer 134c extends between vertical conductive layers 134a and 134b in a horizontal direction across a light-facing or second side of the semiconductor substrate and is laterally coupled between the vertical conductive layers. The terms “horizontal” and “vertical” refer to the orientation shown in the figures, which is the same orientation of a wafer laid flat on a horizontal surface.

The lateral conductive layer 134c may be a doped layer that is doped with the first type of dopants that are the same type of dopants as semiconductor material 114. The lateral conductive layer 134c has a higher doping than semiconductor material 114 and is located on an opposite side of the semiconductor material 114 from the diode structure 106. In an embodiment in which the first type of dopants are N dopants and the second type are P dopants, the lateral conductive layer 134c is part of an anode pickup of the photodiode device 100.

In another embodiment, the first dopants are P dopants and the second dopants are N dopants. In such an embodiment, the doped region 108 may be a P+ doped region, doped well 110 may be a P-well, doped well 112 may be an N-well, and the semiconductor material 114 may be a depleted epitaxial silicon or N-doped silicon. In addition, lateral conductive layer 134c may be an N-doped layer, and the lateral conductive layer 134c may be a cathode pickup or cathode electrode of the device 100. Accordingly, the lateral conductive layer 134c may be an anode electrode or a cathode electrode of the device 100 in different embodiments.

A first vertical conductive layer 134a is on a first side of each DTI structure 104, and a second vertical conductive layer 134b is on a second opposite side of the DTI structure 104. The vertical conductive layers 134a and 134b may be located directly against the insulating liner layer 118 of the DTI structures 104. In another embodiment, one or more liner layer may be present between the vertical conductive layers 134a and 134b and the insulating liner layers 118.

The vertical conductive layers 134a and 134b may be doped semiconductor materials that have the same dopant type as lateral conducive layer 134c. For example, when lateral conducive layer 134c is P-doped, the vertical conductive layers 134a and 134b are also P-doped, and when lateral conducive layer 134c is N-doped, the vertical conductive layers 134a and 134b are also N-doped. The vertical conductive layers 134a and 134b may be formed at the same time as lateral conductive layer 134c using the same implant operation, such that the doping concentration and type of vertical conductive layers 134a and 134b may be substantially the same as those of lateral conductive layer 134c.

In some embodiments, the conductive layers 134 have a doping concentration in the range of 1E17 to 1E21 atoms/cm³. The semiconductor material of conductive layers 134 may be polysilicon. In embodiments, the semiconductor material may be epitaxial silicon, germanium, or other semiconductor materials as known in the art.

The conductive material of vertical conductive layers 134a and 134b is not limited to a doped semiconductor material. In some embodiments, the vertical layers 134a and 134b may comprise a metal material such as tungsten. It is possible to form the lateral conductive layer 134c of a translucent metal material such as a tin oxide as an alternative to a doped semiconductor. The first and second vertical conductive layers 134a and 134b illustrated in FIG. 1B may be part of anode or cathode pickups for a photodiode.

A doped intermediate region 136 is located below each DTI structure 104. The doped intermediate region 136 may be a conductive structure that provides conductive paths between metal wiring beneath the DTI structure 104, e.g. metal wire 126a, and both of the first and second vertical conductive layers 134a and 134b on each side of the DTI structure 104. That is, the doped intermediate region may be an intermediate structure in a conductive path between metal wiring of the photodetector device 100 and conductive layers over the sides of DTI structures 104.

The doped intermediate region 136 may have a width that is at least the same as a width of the first and second vertical conductive layers 134a and 134b, and a height that extends between contact 124a and the base (e.g. the bottom of the insulating liner layer 118) of the DTI structures 104. A width of the doped intermediate region 136 may be about 0.5 to 1.0 μm, for example. In some embodiments, the height of a pixel 102 from the diode structure 106 to a micro lens 132 may be about 7 microns, and the height of doped intermediate regions 136 may be from about 0.5 to 1 μm (500-1000 nm). Other heights are possible, for example for different pixel sizes. As used herein, the term “about” refers to values that are within typical engineering tolerances, e.g. plus or minus five percent.

The doped intermediate region 136 may have a doping level that is the same as or lower than a doping level of the vertical conductive layers 134a and 134b. In an embodiment in which the doped intermediate region 136 is doped using a different implantation from the vertical conductive layers 134a and 134b, the doped intermediate region 136 may have a concentration of 1E16 to 1E18 atoms/cm³, and the vertical conductive layers 134a and 134b may have a concentration of 1E19 to 1E21 atoms/cm³, for example. As will be described in further detail below, the doped intermediate region 136 may have two different doping concentrations.

The doped intermediate region 136 may be coupled to a metal line 126a by a single contact 124a. Accordingly, each doped intermediate region 136 underneath a DTI structure 104 of a pixel 102 may be coupled to metal wiring in the dielectric layer 130 by only one contact 124. That is, in an embodiment, contact 124a is the only contact between the metal line 126a and the doped intermediate region 136 for one DTI structure 104. The doped intermediate region 136 is on a same level of the layer semiconductor material as the diode structure 106, e.g. at least a portion of the doped intermediate region 136 lies on the same horizontal plane as at least a portion of the diode structure 106.

Although not shown in the figures, additional structures may be present in the pixel 102. For example, various liner and oxide layers may be present between structures to promote adhesion, reduce or enhance contact resistance, provide electrical insulation, etc.

The contacts 124 and metal lines 126 are part of a circuit structure of the photodiode device 100. The circuit structure may include circuitry for biasing the diode structure 106 and detecting voltage pulses caused by the incidence of photons. Collectively, the metal lines 126a/b, contacts 124a/b, vertical conductive layers 134a/b and doped intermediate regions 136 may provide an anode structure or a portion of an anode circuit of the photodiode 100.

The contacts 124 extend through, or penetrate, an etch stop layer 128 and a portion of a dielectric layer 130. The contacts 124 may be a metal material or a doped semiconductor, and the metal lines 126b may be tungsten, for example. The etch stop layer 128 may be a nitride or oxide material, and the dielectric layer 130 may be an oxide material such as silicon oxide.

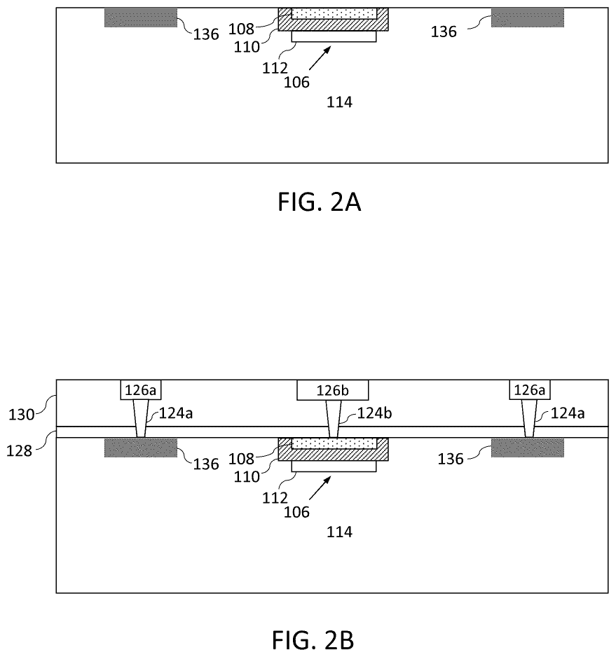

A first embodiment of a process of forming a photodiode device 100 will now be described with respect to FIGS. 2A-2D. As illustrated in FIG. 2A, a process of forming a photodiode device 100 may start with a semiconductor substrate including a semiconductor material 114. In an embodiment, the semiconductor material 114 is an epitaxial silicon material that is formed using an epitaxial growth process, but other embodiments are possible. The semiconductor material 114 may be doped with a second dopant type and may be doped in situ or by performing an implantation step.

The diode structure 106 is formed by performing a series of masking and doping processes as known in the art. Different implantation steps may be performed to form second well 112, first well 110, and doped region 108. The first well 110 and first doped region 108 may comprise a first dopant type, e.g. N type dopants, and the second well may comprise a second dopant type, e.g. P type dopants, that are the same dopant type as semiconductor material 114.

Doped intermediate regions 136 are formed by implanting dopants of the same type as semiconductor material 114, e.g. second or P dopants, into semiconductor material 114. As noted above, the resulting concentration of doped intermediate regions 136 may be from about 1E16 to 1E18 atoms/cm³.

Turning to FIG. 2B, an etch stop layer 128 (e.g. an oxide or nitride layer) and a dielectric layer 130 are formed over the diode structure 106. The etch stop layer 128 and dielectric layer 130 are etched using a mask pattern, and a conductive material is deposited and leveled to form first and second contacts 124a and 124b.

First and second metal lines 126a and 126b are respectively formed over first and second contacts 124a and 124b. The metal lines 126 are located within a dielectric material of dielectric layer 130. Additional conductive and dielectric structures may be formed over dielectric layer 130 to form BEOL structures as known in the art.

To form the structure in FIG. 2C, the wafer is flipped to expose the semiconductor material 114. Next, trenches 140 are formed around diode structure 106. The trenches 140 may be formed by patterning a photoresist layer and performing an etch process. Etching may be performed until the trenches 140 reach a depth that lands on, or extends into, doped intermediate regions 136.

A blanket implantation process may be performed on the exposed surfaces of the semiconductor material 114 including the interior of trenches 140 to form a conductive layer 134 comprising vertical conductive layers 134a and 134b and lateral conductive layer 134c. The implantation process may cause the doped intermediate region 136 to have two regions with different doping concentrations—a first region 136a in a lower part of the doped intermediate region 136 adjacent to the contact 124a, and a second region 136b in an upper part of the doped intermediate region 136 adjacent to the vertical conductive layers 134a and 134b. The first or lower region 136a may have a lower concentration than the second or upper region 136b. For example, portions of the first/lower region 136a may have a concentration of 1E16 to 1E18 atoms/cm³, and portions of the second/upper region 136b may have a concentration of 1E19 to 1E21 atoms/cm³.

Accordingly, an embodiment may comprise a doped intermediate region 136 with a first region 136a with a first concentration of dopants on a contact side of the doped intermediate region (e.g. contact 124a), or lower side with respect to the orientation of the figures, and a second region 136b with a second concentration of dopants on a DTI side (e.g. DTI 104), or upper side with respect to the orientation of the figures, of the doped intermediate region 136. The first concentration of dopants may be lower than the second concentration of dopants.

An insulation liner material 118 may be deposited over exposed surfaces of the entire structure including sidewalls and bases of the trenches 140 to form the structure shown in FIG. 2C.

A conductive material may be deposited to fill trenches 140. Examples of the conductive material are metal materials such as tungsten and copper and doped semiconductor materials. When the conductive material is a semiconductor material, the material may be doped by an in-situ doping process or a separate doping operation. The conductive material may be planarized by a chemical mechanical planarization (CPM) process and etched using an etch mask to form the conductive material 116, thereby completing the DTI structures 104 shown in FIG. 2D. An ARC material is then deposited to form ARC layer 122, resulting in the structure of FIG. 2D. Subsequently, micro-lenses 132 may be formed over respective pixels 102 as shown in FIG. 1B.

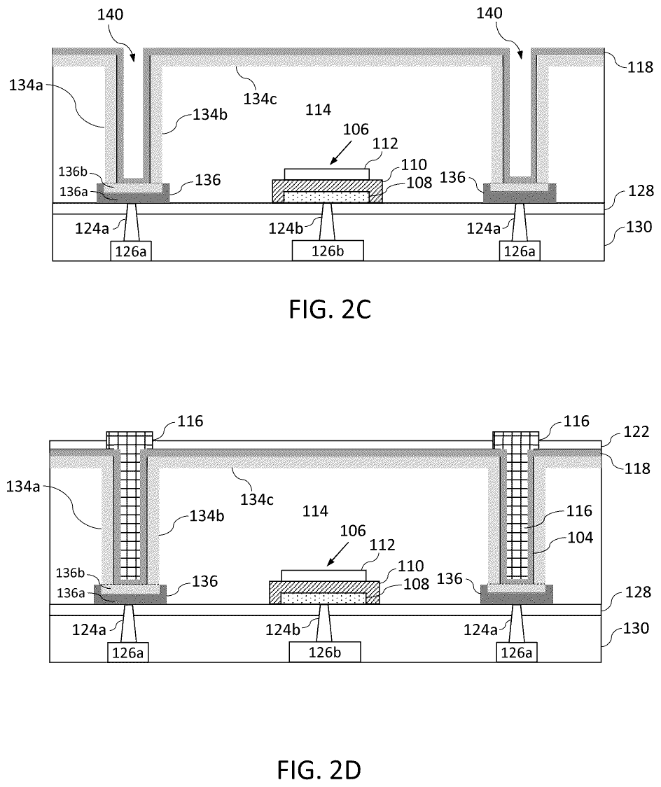

FIG. 3 shows a second embodiment of a pixel 102 of a photodetector device 100. In the embodiment of FIG. 3, the doped intermediate regions 136 may have the same thickness and dopant concentrations as the vertical conductive layers 134. As a result, DTI structures 104 in the embodiment of FIG. 3 may have a greater depth than the embodiment of FIGS. 2A-2D, and doped intermediate regions 136 may have a lesser height.

The embodiment of FIG. 3 may be formed in a similar fashion to the embodiment of FIGS. 2A-2D, except that dopants are not implanted at the step illustrated by FIG. 2A to form the doped intermediate regions 136. Instead, the trenches 140 shown in FIG. 2C are etched to a greater depth, and the doped intermediate regions 136 are formed when dopants are implanted to form conductive layer 134.

Although two specific embodiments have been described above, the scope of the present disclosure is not limited to the specific materials and steps for those embodiments. For example, in another embodiment, one or more of the vertical conductive layers 134a and 134b and the doped intermediate region 136 may comprise a different conductive material such as an in-situ doped material formed by a damascene process, for example, or a metal material. Persons of skill in the art will recognize that various liner and contact materials may be present as well.

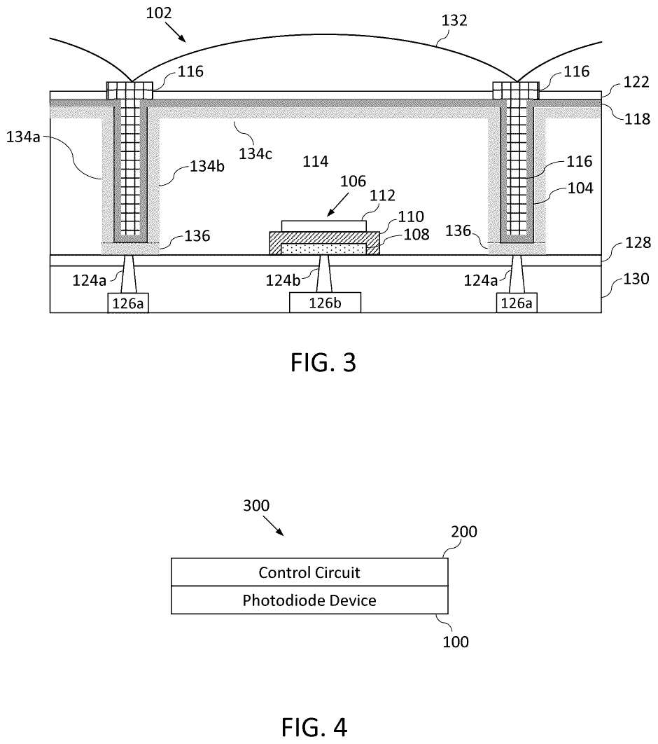

FIG. 4 illustrates an embodiment of a photodetector 300. The photodetector 300 includes a photodiode device 100 according to an embodiment of the present disclosure, and a control circuit 200. The control circuit 200 may include circuitry to control operations of photodiode device 100 and to process signals received from the photodiode device 100. In an embodiment, the photodiode device 100 is coupled to control circuit 200 through metal lines 126, which may be part of the control circuit.

In some embodiments, the photodiode device 100 is on a separate die from the control circuit 200, and the dies may be stacked in a three-dimensional structure and/or coupled to control circuit 200 by an interposer substrate. Accordingly, the photodetector 300 in FIG. 4 may be embodied in various forms.

The resulting photodiode 100 is suitable for use in a variety of electronic devices, including imaging devices and focusing aides, optical devices including fiber-optic communication devices, cell phones, computer devices, security equipment, detection equipment including LiDAR, IoT and general household equipment, etc. The photodiode may be an avalanche photodiode or a single photon avalanche photodiode, for example.

Embodiments of the present disclosure have advantages over conventional designs. In some conventional designs, contacts are coupled to doped regions within the semiconductor material 114 of the pixel instead of vertical conductive layers. Such doped regions occupy a significant amount of space in the lateral dimension. Embodiments of the present disclosure eliminate the need for such doped regions within the pixel area, thereby reducing pixel pitch for a given fill factor, or improving fill factor for the same pixel size of conventional designs. Another advantage of embodiments of the present disclosure is lower resistance due to the vertical conductive layers 134.

There is a tradeoff between pixel pitch and fill factor depending on the size of the active area and the intrinsic space. In embodiments of the present disclosure, photon detection probability may be maintained or increased and dark current is not substantially degraded compared to conventional devices.

Additional advantages result from the presence of a single contact 124 coupled to a single wire 126 under a DTI structure 104. Conventional designs may employ multiple contacts and respective wires for a DTI structure, e.g. at least one contact and wire on each side of the DTI structure. Furthermore, the doped intermediate region 136 provides a relatively large landing area for the contact 124a. Accordingly, embodiments may reduce the number of structures and associated tolerances, thereby simplifying fabrication and increasing reliability.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A photodiode device, comprising:
a plurality of pixels, each of the pixels including a diode structure on a first side of a layer of semiconductor material and a lens on a second side of the layer of semiconductor material;
a deep trench isolation (DTI) structure between adjacent pixels of the plurality of pixels;
a first vertical conductive layer over a first side of the DTI structure;
a second vertical conductive layer over a second side of the DTI structure; and
a doped intermediate region between a contact at the first side of the layer of semiconductor material and a base of the DTI structure, and in direct contact with the contact and the first and second vertical conductive layers.

2. The photodiode device of claim 1, wherein the doped intermediate region has a height of about 500 to 1000 nanometers.

3. The photodiode device of claim 1, wherein the doped intermediate region and the first and second vertical conductive layers have the same dopant concentration.

4. The photodiode device of claim 3, wherein the dopant concentration of the doped intermediate region and the first and second vertical conductive layers is from about 1E19 to 1E21 atoms/cm³.

5. The photodiode device of claim 1, wherein the doped intermediate region comprises:
a first region with a first concentration of dopants on a contact side of the doped intermediate region; and
a second region with a second concentration of dopants on a DTI side of the doped intermediate region,
wherein the first concentration of dopants is lower than the second concentration of dopants.

6. The photodiode device of claim 5, wherein the first concentration of dopants is from about 1E16 to 1E18 atoms/cm³, and the second concentration of dopants is from about 1E19 to 1E21 atoms/cm³.

7. The photodiode device of claim 1, wherein the first vertical conductive layer, the second vertical conductive layer, the layer of semiconductor material and the doped intermediate region are all doped with P-type dopants.

8. The photodiode device of claim 1, wherein the contact is coupled to a metal line, and the contact is the only contact between the metal line and the doped intermediate region under the DTI structure.

9. The photodiode device of claim 1, wherein the doped intermediate region is at a same level of the layer of semiconductor material as the diode structure.

10. The photodiode device of claim 1, wherein the photodiode device is a single-photon avalanche diode device.

11. A photodetector, comprising:
a photodiode device; and
a control circuit configured to control an operation of the photodiode device, wherein the photodiode device includes:
a plurality of pixels, each of the pixels including a diode structure on a first side of a layer of semiconductor material and a lens on a second side of the layer of semiconductor material;
a deep trench isolation (DTI) structure isolating adjacent pixels of the plurality of pixels from one another;
a first vertical conductive layer over a first side of the DTI structure;
a second vertical conductive layer over a second side of the DTI structure; and
a doped intermediate region that extends between a contact at the first side of the layer of semiconductor material and a base of the DTI structure, and electrically couples the contact to the first and second vertical conductive layers.

12. The photodetector of claim 11, wherein the doped intermediate region has a height of about 500 to 1000 nanometers.

13. The photodetector of claim 11, wherein the doped intermediate region and the first and second vertical conductive layers have the same dopant concentration.

14. The photodetector of claim 13, wherein the dopant concentration of the doped intermediate region and the first and second vertical conductive layers is from about 1E19 to 1E21 atoms/cm³.

15. The photodetector of claim 11, wherein the doped intermediate region comprises:
a first region with a first concentration of dopants on a contact side of the doped intermediate region; and
a second region with a second concentration of dopants on a DTI side of the doped intermediate region,
wherein the first concentration of dopants is lower than the second concentration of dopants.

16. The photodetector of claim 15, wherein the first concentration of dopants is from about 1E16 to 1E18 atoms/cm³, and the second concentration of dopants is from about 1E19 to 1E21 atoms/cm³.

17. The photodetector of claim 11, wherein the first vertical conductive layer, the second vertical conductive layer, the layer of semiconductor material and the doped intermediate region are all doped with P-type dopants.

18. The photodetector of claim 11, wherein the contact is coupled to a metal line, and the contact is the only contact between the metal line and the doped intermediate region under the DTI structure.

19. The photodetector of claim 11, wherein the doped intermediate region is at a same level of the layer of semiconductor material as the diode structure.

20. A method of forming a photodiode device, the method comprising:
forming diode structures on a first side of a layer of semiconductor material;
forming a contact between two adjacent diode structures;
forming a doped intermediate region over the contact;
forming first and second vertical conductive layers electrically coupled to the doped intermediate region;
forming a deep trench isolation (DTI) structure between the first and second vertical conductive layers; and
forming a lens on a second side of the semiconductor material,
wherein the first and second vertical conductive layers cover sides of the DTI structure and the doped intermediate region electrically couples the contact to the first and second vertical conductive layers.
